(19) United States
(12) Patent Application Publication
(10) Pub. No.: US 2025/0069983 A1
(43) Pub. Date: Feb. 27, 2025

(54) CERAMIC SUBSTRATE UNIT AND MANUFACTURING METHOD THEREFOR

(71) Applicant: AMOSENSE CO., LTD., Cheonan-si, Chungcheongnam-do (KR)

(72) Inventor: Jihyung LEE, Cheonan-si (KR)

(73) Assignee: AMOSENSE CO., LTD., Cheonan-si, Chungcheongnam-do (KR)

(21) Appl. No.: 18/726,786

(22) PCT Filed: Jan. 3, 2023
(86) PCT No.: PCT/KR2023/000056

§ 371 Date: Jul. 5, 2024

(30) Foreign Application Priority Data
Jan. 4, 2022 (KR) 10-2022-0000650
Jan. 4, 2022 (KR) 10-2022-0000674

(51) Int. Cl. H01L 23/373; H01L 21/48; H01L 23/15; H01L 23/473; H01L 23/498; H01L 25/065

(52) U.S. Cl. CPC H01L 23/3731; H01L 21/4882; H01L 23/15; H01L 23/3736; H01L 23/473; H01L 23/49838; H01L 25/0655

(57) ABSTRACT

The present invention relates to a ceramic substrate unit and a manufacturing method therefor. The ceramic substrate unit comprises: a ceramic substrate having metal layers on the upper and lower surfaces of the ceramic substrate; a heat dissipation spacer bonded to the upper metal layer of the ceramic substrate; and a heat sink bonded to the lower metal layer of the ceramic substrate, wherein the heat dissipation spacer is provided with an electrode in a region to which a semiconductor chip is bonded, so that the semiconductor chip may be bonded in the form of a flip chip.

### TECHNICAL FIELD

The present disclosure relates to a ceramic substrate unit and a method of manufacturing the same, and more particularly, to a ceramic substrate unit having a bonding structure for a heat sink including a plurality of protrusions for water-cooled heat dissipation and a ceramic substrate, and a method of manufacturing the same.

### BACKGROUND ART

In general, an electric vehicle requires an inverter for converting a DC voltage provided from a high voltage battery into an AC 3-phase voltage for driving a motor.

The inverter is assembled with a power module for supplying a high voltage of the battery for driving by adjusting the high voltage in a state suitable for the motor. The power module includes a semiconductor chip for the conversion of power. The semiconductor chip generates high-temperature heat due to a high-voltage and high-current operation. If such heat continues, there are problems in that the semiconductor chip is deteriorated and performance of the power module is reduced.

In order to solve the problems, a phenomenon in which the semiconductor chip is deteriorated due to heat is prevented through a heat dissipation function of the heat sink by providing the heat sink on at least one surface of a ceramic or metal substrate.

The heat sink is manufactured by using a metal material having high thermal conductivity, such as copper or aluminum. The heat sink manufactured using such metal has a limit in heat dissipation. If heat over the limit is generated, it becomes a cause of a failure because cooling efficiency is suddenly reduced.

Furthermore, the substrate on which the semiconductor chip is mounted has a problem in that the characteristics of the substrate are deteriorated due to bending attributable to heat.

The contents described in the Background Art are to help the understanding of the background of the disclosure, and may include contents that are not a disclosed conventional technology.

### DISCLOSURE

### Technical Problem

The present disclosure has been invented to solve the aforementioned problems, and an object of the present disclosure is to provide a ceramic substrate unit that enables heat generated from a semiconductor chip to be effectively discharged and a method of manufacturing the same.

### Technical Solution

A ceramic substrate unit for achieving the above object according to an embodiment of the present disclosure may include a ceramic substrate in which metal layers are provided on upper and lower surfaces of a ceramic base, a heat dissipation spacer bonded to the upper metal layer of the ceramic substrate, and a heat sink bonded to the lower metal layer of the ceramic substrate. The heat dissipation spacer may include an electrode in an area to which a semiconductor chip is bonded so that the semiconductor chip is bonded to the heat dissipation spacer in a flip chip form.

The at least two semiconductor chips may be bonded to the heat dissipation spacer.

The heat dissipation spacer may include a first heat dissipation spacer that has a shape corresponding to the upper metal layer and has a lower surface bonded to the upper metal layer and that includes a wiring part including the electrode and at least one second heat dissipation spacer that is disposed at a location that faces one end of the electrode and that has an upper surface bonded to the electrode of the semiconductor chip.

The wiring part may include an insulating layer disposed in a groove formed on the first heat dissipation spacer and made of an insulating material and the electrode disposed on the insulating layer and extended along the groove from the one end to form a wire.

The electrode may be disposed to be inserted at a predetermined depth on an upper surface of the insulating layer and provided as a pair. The pair of electrodes may be disposed at an interval in the width direction of the insulating layer.

The heat sink may include a plane part having an upper surface coming into contact with the lower metal layer and a plurality of protrusions disposed on a lower surface of the plane part at intervals and configured to form a passage along which a liquid refrigerant flows.

The plurality of protrusions may be disposed in an external refrigerant circulation part. The liquid refrigerant that circulates through the refrigerant circulation part may be heat-exchanged with the plurality of protrusions.

The plurality of protrusions may each have a rod shape and may be horizontally disposed at intervals.

Furthermore, the plurality of protrusions may each have at least one pin shape, among a cylinder, a polygonal column, a teardrop shape, or a diamond shape.

A material of the heat sink may be any one of Cu, Al, and a Cu alloy.

The heat dissipation spacer may be made of a CPC material in which Cu or MoCu or Cu, CuMo, and Cu have been sequentially stacked.

A ceramic substrate unit according to another embodiment of the present disclosure may include a ceramic substrate in which metal layers are provided on upper and lower surfaces of a ceramic base, a heat dissipation spacer that is bonded to the upper metal layer of the ceramic substrate and on which a semiconductor chip is mounted, a wiring part including an insulating layer bonded to an upper surface of the heat dissipation spacer and an electrode disposed on the insulating layer and connected to the semiconductor chip to form a wire, and a heat sink bonded to the lower metal layer of the ceramic substrate.

In this case, the insulating layer of the wiring part may be boned to the upper surface of the heat dissipation spacer via a brazing bonding layer. The brazing bonding layer may be made of a material including at least one of Ag, Cu, AgCu, and AgCuTi. Furthermore, the electrode of the wiring part may be connected to the semiconductor chip through a wire.

A method of manufacturing a ceramic substrate unit according to an embodiment of the present disclosure may include a step of preparing a ceramic substrate in which metal layers are provided on upper and lower surfaces of a ceramic base, a step of preparing a heat dissipation spacer including an electrode for bonding a semiconductor chip in a flip chip form, a step of bonding the heat dissipation spacer to the upper metal layer of the ceramic substrate, and a step of bonding a heat sink to the lower metal layer of the ceramic substrate.

In the step of preparing the heat dissipation spacer, the heat dissipation spacer may include a first heat dissipation spacer that has a shape corresponding to the upper metal layer and has a lower surface bonded to the upper metal layer and that includes a wiring part including the electrode and at least one second heat dissipation spacer that is disposed at a location that faces one end of the electrode and that has an upper surface bonded to the electrode of the semiconductor chip.

In the step of preparing the heat dissipation spacer, the wiring part may include an insulating layer disposed in a groove formed on the first heat dissipation spacer and made of an insulating material and the electrode disposed on the insulating layer and extended along the groove from the one end to form a wire.

In the step of preparing the heat dissipation spacer, the electrode may be disposed to be inserted at a predetermined depth on an upper surface of the insulating layer and provided as a pair, and the pair of electrodes may be disposed at an interval in the width direction of the insulating layer.

In the step of bonding the heat dissipation spacer to the upper metal layer of the ceramic substrate, the heat dissipation spacer may be bonded to the upper metal layer via a first bonding layer that is disposed between the upper metal layer and the heat dissipation spacer. The first bonding layer may be made of a material including at least one of Ag, Cu, AgCu, and AgCuTi or made of Ag sintering paste.

In the step of bonding the heat sink to the lower metal layer of the ceramic substrate, the heat sink may be bonded to the lower metal layer via a second bonding layer that is disposed between the lower metal layer and a plane part of the heat sink. The second bonding layer may be made of a material including at least one of Ag, Cu, AgCu, and AgCuTi or made of Ag sintering paste.

### Advantageous Effects

The present disclosure can lower an inductance value to the maximum and improve heat dissipation performance, because the electrode is provided in an area to which the semiconductor chip is bonded in the heat dissipation spacer, the semiconductor chip is bonded in a flip chip form, and wire bonding is omitted. Furthermore, an electrical risk factor which may occur upon wire bonding can be removed, a rate voltage or current can be converted, and reliability and efficiency upon use in high power can be improved.

Furthermore, the present disclosure can improve heat dissipation efficiency because heat generated from the semiconductor chip is transferred to the ceramic substrate and the heat sink through the heat dissipation spacer.

Furthermore, in the present disclosure, the heat dissipation spacer does not need to be etched for the connection of a circuit and an electrode pattern design can be freely performed, because the wiring part that plays a role as an electric track is aligned with and bonded to an upper surface of the heat dissipation spacer after the wiring part is separately processed.

Furthermore, the present disclosure has a water-cooled heat dissipation structure in which the plurality of protrusions is cooled by a liquid refrigerant that continuously circulates by coming into direct contact with the liquid refrigerant. Accordingly, heat can be rapidly absorbed and discharged by adjusting the flow velocity of the liquid refrigerant, and a heat dissipation effect can be maximized compared to the existing air-cooled heat dissipation structure.

Furthermore, in the present disclosure, although high-temperature heat is generated from the semiconductor chip, etc., the overheating of the ceramic substrate can be prevented and the semiconductor chip can be maintained at a constant temperature so that the semiconductor chip is not deteriorated because the heat is forcedly cooled by a liquid refrigerant that consecutively circulates.

Furthermore, in the present disclosure, the flow velocity, cooling efficiency, etc. of a liquid refrigerant can be easily controlled in response to a change in the shape, number, and arrangement form of the plurality of protrusions because the liquid refrigerant is provided to move between the plurality of protrusions.

### DESCRIPTION OF DRAWINGS

FIG. 1 is a plane-side perspective view illustrating a ceramic substrate unit according to an embodiment of the present disclosure.

FIG. 2 is a bottom-side perspective view illustrating the ceramic substrate unit according to an embodiment of the present disclosure.

FIG. 3 is a side view illustrating the ceramic substrate unit according to an embodiment of the present disclosure.

FIG. 4 is a plane view illustrating the ceramic substrate unit according to an embodiment of the present disclosure.

FIG. 5 is a cross-sectional view taken along line A-A′ in FIG. 4.

FIG. 6 is a conceptual view illustrating a construction in which the ceramic substrate unit according to an embodiment of the present disclosure is mounted on a refrigerant circulation part and a circulation driving part is connected to the refrigerant circulation part.

FIG. 7 is a plane view illustrating a ceramic substrate unit according to another embodiment of the present disclosure.

FIG. 8 is a cross-sectional view taken along line A-A′ in FIG. 7.

FIG. 9 is a plane-side perspective view illustrating a ceramic substrate unit according to still another embodiment of the present disclosure.

FIG. 10 is a conceptual view illustrating a construction in which the ceramic substrate unit according to still another embodiment of the present disclosure is mounted on a refrigerant circulation part and a circulation driving part is connected to the refrigerant circulation part.

FIG. 11 is a bottom-side perspective view illustrating the ceramic substrate unit according to still another embodiment of the present disclosure.

FIG. 12 is a plane view illustrating a construction in which a semiconductor chip and a lead frame are connected to the ceramic substrate unit according to still another embodiment of the present disclosure.

FIG. 13 is a flowchart illustrating a method of manufacturing a ceramic substrate unit according to an embodiment of the present disclosure.

### MODE FOR INVENTION

Hereinafter, embodiments of the present disclosure are described in detail with reference to the accompanying drawings.

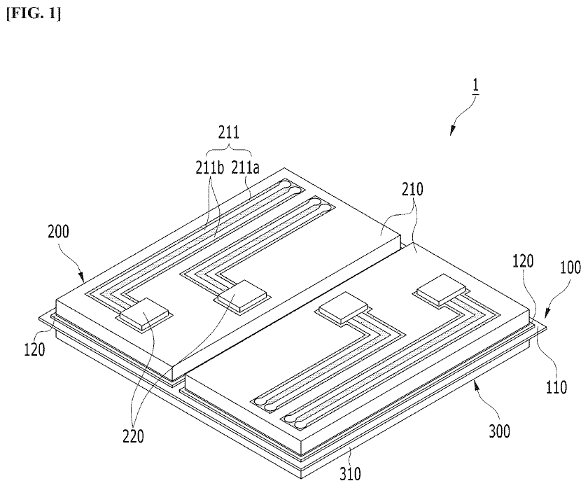

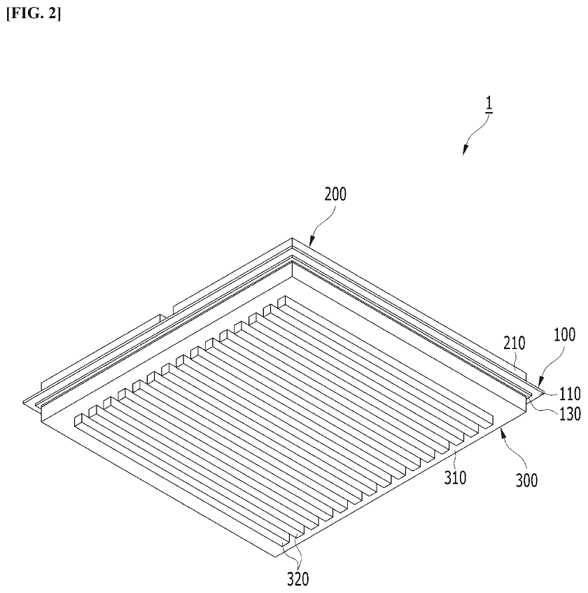

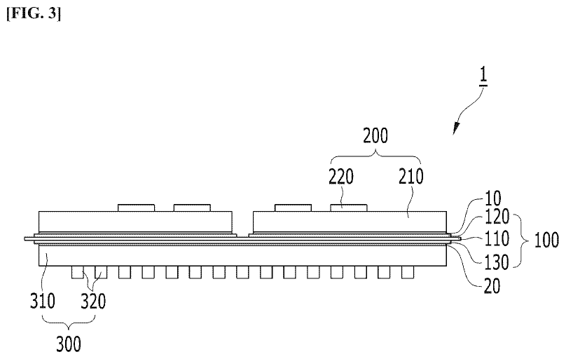

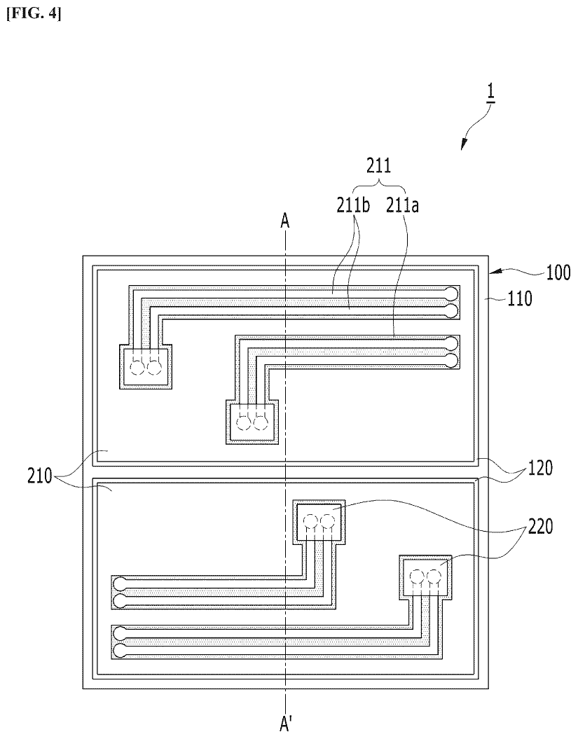

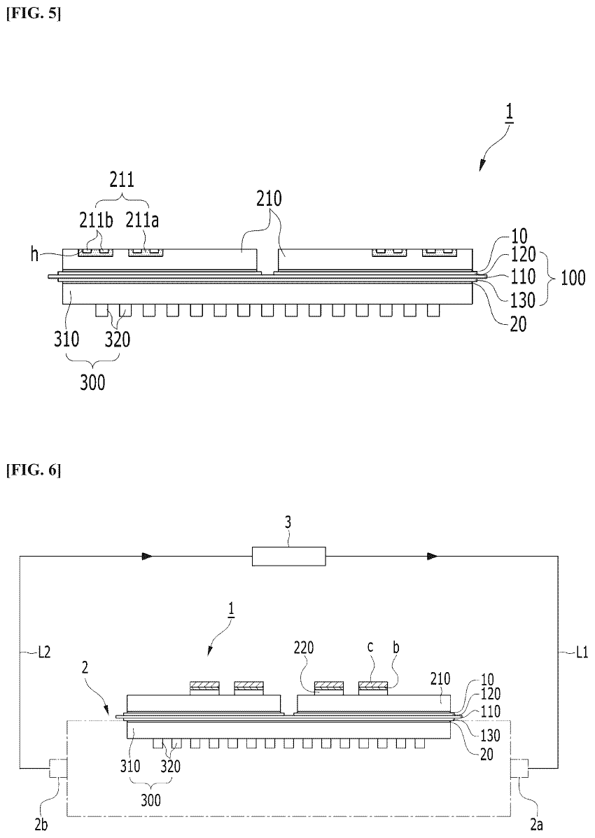

FIG. 1 is a plane-side perspective view illustrating a ceramic substrate unit according to an embodiment of the present disclosure. FIG. 2 is a bottom-side perspective view illustrating the ceramic substrate unit according to an embodiment of the present disclosure. FIG. 3 is a side view illustrating the ceramic substrate unit according to an embodiment of the present disclosure. FIG. 4 is a plane view illustrating the ceramic substrate unit according to an embodiment of the present disclosure. FIG. 5 is a cross-sectional view taken along line A-A′ in FIG. 4.

As illustrated in FIGS. 1 to 3, a ceramic substrate unit 1 according to an embodiment of the present disclosure may be constructed to include a ceramic substrate 100, a heat dissipation spacer 200, and a heat sink 300.

The ceramic substrate 100 may be any one of an active metal brazing (AMB) substrate, a direct bonded copper (DBC) substrate, and a thick printing copper (TPC) substrate. The substrates are substrates in each of which metal is directly bonded to a ceramic base. In an embodiment of the present disclosure, the ceramic substrate 100 may include a ceramic base 110, and an upper metal layer 120 and a lower metal layer 130 on upper and lower surfaces of the ceramic base 110 so that heat dissipation efficiency of heat that is generated from a semiconductor chip can be increased. The ceramic base 110 may be made of an oxide-based or nitride-based ceramic material. For example, the ceramic base 110 may be any one of alumina (Al₂O₃), AlN, SiN, Si3N₄, and zirconia toughened alumina (ZTA), but is not limited thereto.

The upper metal layer 120 and the lower metal layer 130 may each be made of one of Cu, Al, and a Cu alloy having excellent thermal conductivity, but is not limited thereto.

The upper metal layer 120 may be formed on the upper surface of the ceramic base 110 and may be provided in a circuit pattern shape. For example, the upper metal layer 120 may be formed as an electrode pattern in an area on which the semiconductor chip or a peripheral part will be mounted.

The lower metal layer 130 may be formed on the lower surface of the ceramic base 110, and may be provided as a flat panel in order to facilitate the transfer of heat. The lower metal layer 130 having such a flat panel form may experience a phenomenon in which the ceramic substrate 100 is bent in a high temperature environment because the lower metal layer has a great volume difference compared to a total volume of the upper metal layer 120 that is formed as the electrode pattern. Accordingly, the present disclosure can suppress a bending phenomenon which occurs due to a difference between the volumes of the upper and lower metal layers 120 and 130 by integrally brazing-bonding the heat sink 300 to be described later to the ceramic substrate 100.

The heat dissipation spacer 200 is bonded to the upper metal layer 120 of the ceramic substrate 100, and includes an electrode 211b in an area to which a semiconductor chip c (refer to FIG. 6). Accordingly, the semiconductor chip c may be bonded to the heat dissipation spacer in a flip chip form. In this case, at least two semiconductor chips c may be bonded to the heat dissipation spacer 200.

Specifically, the heat dissipation spacer 200 may be constructed to include a first heat dissipation spacer 210 and at least one second heat dissipation spacer 220.

The first heat dissipation spacer 210 is formed in a shape corresponding to the upper metal layer 120 of the ceramic substrate 100, and may have a lower surface bonded to the upper metal layer 120 and have a predetermined thickness for heat dissipation.

Referring to FIGS. 4 and 5, the first heat dissipation spacer 210 may include a wiring part 211. The wiring part 211 may be disposed in a groove h formed in the top of the first heat dissipation spacer 210.

In this case, the wiring part 211 may be constructed to include an insulating layer 211a and the electrode 211b. The insulating layer 211a may be disposed in the groove h formed in the top of the first heat dissipation spacer 210, and may be made of an insulating material. For example, polyimide (PI), FR4, and ceramic (alumina, ZTA, AlN, Si₃N₄, etc.) may be used as the insulating layer, but the present disclosure is not limited thereto.

The electrode 211b may be disposed on the insulating layer 211a. In this case, the electrode 211b may be disposed to be inserted at a predetermined depth on an upper surface of the insulating layer 211a, and may be provided as a pair. The pair of electrodes may be disposed at an interval in the width direction of the insulating layer 211a.

The electrode 211b may form a wire by extending along the groove h of the first heat dissipation spacer 210 from one end thereof that is disposed at a location that faces the second heat dissipation spacer 220. That is, the electrode 211b has the one end disposed at the location that faces the second heat dissipation spacer 220 and thus may play a role as an electric track that transfers an electrical signal by being connected to the semiconductor chip c bonded to the second heat dissipation spacer 220. For example, Cu, Ag, Ni—Au, W, Mo, MoW, etc. may be used for the electrode 211b, but the present disclosure is not limited thereto.

The at least one second heat dissipation spacer 220 may be disposed at a location that faces the one end of the electrode 211b. An electrode of the semiconductor chip c may be bonded to an upper surface of the second heat dissipation spacer. In this case, a gate terminal of the semiconductor chip c may be connected to the second heat dissipation spacer 220. The first heat dissipation spacer 210 may play a role as a source or a drain that is responsible for the input and output of a high current.

The semiconductor chip c that is bonded to the second heat dissipation spacer 220 may be a semiconductor chip of SiC, GaN, Si, LED, VCSEL, etc. The semiconductor chip c may be bonded to the upper surface of the second heat dissipation spacer 220 in a flip chip form by a bonding layer b (refer to FIG. 6) including a solder or Ag paste.

The at least one second heat dissipation spacer 220 may be bonded and formed at a location that faces the one end of the electrode 211b on an upper surface of the first heat dissipation spacer 210 or may be formed integrally with the first heat dissipation spacer 210. The second heat dissipation spacer 220 may have a small-sized block form in which the second heat dissipation spacer has a size of 0.5 mm×0.5 mm or more and a thickness of 0.3 mm or more. The second heat dissipation spacer 220 may be processed to have a proper size by etching, and machine processing may be further performed on the second heat dissipation spacer, if necessary.

As described above, the present disclosure can lower an inductance value to the maximum and improve heat dissipation performance because the electrode 211b is provided in the heat dissipation spacer 200 and bonded to the semiconductor chip c in a flip chip form and wire bonding is omitted. Furthermore, an electrical risk factor which may occur upon wire bonding can be removed, a rate voltage or current can be converted, and reliability and efficiency upon use for high power can be improved. Furthermore, heat dissipation efficiency can be improved because heat generated from the semiconductor chip c is transferred to the ceramic substrate 100 and the heat sink 300 through the heat dissipation spacer 200.

The heat dissipation spacer 200 may be made of at least one of Cu, Al, AlSiC, CuMo, CuW, Cu/CuMo/Cu, Cu/Mo/Cu, and Cu/W/Cu or a composite material of them. Preferably [symbol] , the heat dissipation spacer 200 may be formed of at least one of Cu, Mo, a CuMo alloy, and a CuW alloy having an excellent coefficient of thermal expansion and excellent thermal conductivity.

For example, the heat dissipation spacer 200 may have a 3-layer structure of Cu/CuMo/Cu. A CPC material on which Cu, CuMo, and Cu have been sequentially stacked is advantageous for heat dissipation due to high thermal conductivity, and can minimize the occurrence of bending upon brazing bonding with the upper metal layer 120 of the ceramic substrate 100 because the CPC material has a low coefficient of thermal expansion.

The heat dissipation spacer 200 may be provided in the state in which thermal stress, thermal deformation, etc. have been removed through thermal treatment. If thermal stress and thermal deformation are previously removed, bonding strength can be improved because thermal stress that occurs due to thermal expansion and thermal contraction in a process of brazing-bonding the upper metal layer 120 of the ceramic substrate 100 and the heat dissipation spacer 200 is reduced. Furthermore, a heat transfer effect becomes excellent because a bonding portion is not damaged.

The heat dissipation spacer 200 may be bonded to the upper metal layer 120 of the ceramic substrate 100 via a first bonding layer 10. In this case, the first bonding layer 10 may be a brazing bonding layer or an Ag sintering bonding layer that is made of a material including at least one of Ag, Cu, AgCu, and AgCuTi. If the first bonding layer 10 is the brazing bonding layer, the brazing bonding layer may be disposed between the upper metal layer 120 of the ceramic substrate 100 and the heat dissipation spacer 200, and may integrally bond the ceramic substrate 100 and the heat dissipation spacer 200 at a brazing temperature. The brazing temperature may be 450° C. or more. Ag, AgCu, and AgCuTi can each improve heat dissipation efficiency because Ag, AgCu, and AgCuTi each play a role of increasing an adhesive force and also facilitate the transfer of heat between the ceramic substrate 100 and the heat dissipation spacer 200 due to high thermal conductivity. The first bonding layer 10 may be formed by any one method, among plating, paste application, and foil attachment, and may have a thickness of about 0.005 mm to 1.0 mm.

If the first bonding layer 10 is the Ag sintering bonding layer, Ag sintering paste may be disposed between the upper metal layer 120 of the ceramic substrate 100 and the heat dissipation spacer 200. The ceramic substrate 100 and the heat dissipation spacer 200 may be bonded by sintering the Ag sintering paste at a low temperature of about 200° C. Such Ag sintering bonding has high high-temperature safety and excellent bonding strength of about 80 MPa because the melting point of a sintering body rises to 700° C. or more after the bonding.

Meanwhile, the ceramic substrate 100 and the heat dissipation spacer 200 may be temporarily bonded through thermochemical bonding and then brazing-bonded. In this case, the thermochemical bonding may be bonding using heat fusion, adhesives, a sticking agent, etc. As described above, the ceramic substrate 100 and the heat dissipation spacer 200 are airtightly bonded by a bonding method, such as brazing bonding or Ag sintering bonding, and thus each have high bonding strength and excellent high-temperature reliability.

FIG. 6 is a conceptual view illustrating a construction in which the ceramic substrate unit according to an embodiment of the present disclosure is mounted on a refrigerant circulation part and a circulation driving part is connected to the refrigerant circulation part.

As illustrated in FIG. 6, the heat sink 300 has been bonded to the lower metal layer 130 of the ceramic substrate 100 and may be made of any one material having high thermal conductivity, among Cu, Al, and a Cu alloy, for heat dissipation. The heat sink 300 may include a plane part 310 and a plurality of protrusions 320. As will be described later, the plurality of protrusions 320 may form a passage along which a liquid refrigerant flows. The heat sink 300 may be a heat sink, such as a micro channel, a pin fin, a micro jet, a slit, or a duct type. In the present embodiment, the heat sink 300 including the plane part 310 and the plurality of protrusions 320 is described.

The plane part 310 has an upper surface coming into direct contact with the lower metal layer 130, and may be formed in a flat panel form so that an adhesive force can be increased by increasing a bonding area with the lower metal layer 130 to the maximum. The plurality of protrusions 320 is disposed on the lower surface of the plane part 310 at intervals, and may form a passage along which a liquid refrigerant flows. The present embodiment illustrates a slit type heat sink in which the plurality of protrusions 320 each having a rod shape are horizontally disposed at intervals, but the present disclosure is not limited thereto. The plurality of protrusions 320 may have various pin forms, such as a cylinder, a polygonal column, a teardrop shape, and a diamond shape. A shape of the protrusion 320 may be implemented by molding processing, etching processing, milling, or other processing.

The plurality of protrusions 320 may be disposed in a refrigerant circulation part 2. The refrigerant circulation part 2 may include an inlet 2a into which a liquid refrigerant is introduced, an outlet 2b from which the liquid refrigerant is discharged, and an internal flow path (not illustrated) from the inlet 2a to the outlet 2b. In this case, the liquid refrigerant that is introduced through the inlet 2a of the refrigerant circulation part 2 may be discharged through the outlet 2b via the internal flow path. A form and size of the internal flow path, that is, a path along which the liquid refrigerant moves between the inlet 2a and the outlet 2b, may be variously designed and changed. Accordingly, a detailed description of the internal flow path itself of the refrigerant circulation part 2 is omitted.

A circulation driving part 3 is connected to the refrigerant circulation part 2, and may circulate a liquid refrigerant by using the driving force of a pump (not illustrated). In this case, the inlet 2a of the refrigerant circulation part 2 may be connected to the circulation driving part 3 through a first circulation line L1. The outlet 2b of the refrigerant circulation part 2 may be connected to the circulation driving part 3 through a second circulation line L2. That is, the circulation driving part 3 may continuously circulate the liquid refrigerant along a circulation path including the first circulation line L1, the refrigerant circulation part 2, and the second circulation line L2. In this case, the liquid refrigerant may be deionized water, but is not limited thereto. Liquid nitrogen, alcohol, or other solvents may be used as the liquid refrigerant, if necessary.

The liquid refrigerant that is supplied by the circulation driving part 3 is introduced into the inlet 2a of the refrigerant circulation part 2 through the first circulation line L1, moves along the internal flow path formed in the refrigerant circulation part 2, and is discharged through the outlet 2b. Thereafter, the liquid refrigerant may move to the circulation driving part 3 again through the second circulation line L2. Although not illustrated in detail, the circulation driving part 3 may include a heat exchanger (not illustrated). The heat exchanger of the circulation driving part 3 may lower a temperature of the liquid refrigerant the temperature of which has risen while passing through the internal flow path of the refrigerant circulation part 2. The circulation driving part 3 may supply the liquid refrigerant having the temperature lowered by the heat exchanger to the first circulation line L1 again by using the driving force of the pump.

As described above, the refrigerant circulation part 2 may be provided so that the liquid refrigerant supplied by the circulation driving part 3 is continuously circulated. In this case, the plurality of protrusions 320 may be disposed in the internal flow path of the refrigerant circulation part 2, and may perform a heat exchange on the liquid refrigerant that continuously circulates along the internal flow path by coming into direct contact with the liquid refrigerant. That is, the plurality of protrusions 320 has a water-cooled heat dissipation structure in which the plurality of protrusions can be directly cooled by the liquid refrigerant that consecutively circulates.

The plurality of protrusions 320 can prevent the overheating of the ceramic substrate 100 because the plurality of protrusions is forcedly cooled by the liquid refrigerant that consecutively circulates although high-temperature heat is generated from the semiconductor chip c, etc., and can maintain a temperature of the semiconductor chip c at a constant temperature so that the semiconductor chip is not deteriorated. That is, although high-temperature heat of about 100° C. or more is generated in the semiconductor chip c, the liquid refrigerant that circulates along the internal flow path of the refrigerant circulation part 2 can rapidly cool heat that is transferred to the plurality of protrusions 320 because a temperature of the liquid refrigerant is about 25° C.

Conventionally, a base plate for heat dissipation is soldering-bonded to a ceramic substrate. Soldering paste that is used in this case, such as Ag epoxy, has problems in that cooling efficiency is low because the soldering paste has low thermal conductivity of about 110 W/m·K and a manufacturing process is complicated because a process of coating a thermal interface material (TIM) substance, such as graphite, etc. need to be additionally performed.

In contrast, in the present disclosure, the heat sink 300 including the plane part 310 and the plurality of protrusions 320 is brazing-bonded to the ceramic substrate 100. A material, such as Ag, AgCu, or AgCuTi that is used upon brazing bonding has thermal conductivity of about 350 W/m·K or more, which is about more than three times compared to a conventional technology. Accordingly, a heat dissipation effect can be maximized. Furthermore, a process can be simplified and energy and costs can be reduced, compared to a conventional technology.

Furthermore, the ceramic substrate unit 1 according to an embodiment of the present disclosure has a construction in which the heat sink 300 and the ceramic substrate 100 have been integrated and has a structure in which the ceramic substrate unit can directly cool heat generated from the semiconductor chip C, so that the ceramic substrate unit can increase heat dissipation performance while implementing weight lightening and miniaturization.

Furthermore, the ceramic substrate unit 1 according to an embodiment of the present disclosure has the water-cooled heat dissipation structure, so that the ceramic substrate unit can rapidly absorb and discharge heat by changing the flow velocity of a liquid refrigerant and thus can maximize a heat dissipation effect compared to the existing air-cooled heat dissipation structure.

A shape, number, and arrangement form of the plurality of protrusions 320 may be variously changed based on pre-simulation results upon design. The flow velocity, flow rate, cooling efficiency, etc. of a liquid refrigerant can be easily controlled by changing a shape, number, and arrangement form of the plurality of protrusions 320 because the liquid refrigerant flows between the plurality of protrusions 320.

The ceramic substrate 100 and the heat sink 300 may be bonded together by a second bonding layer 20. In this case, the second bonding layer 20 may be a brazing bonding layer or an Ag sintering bonding layer that is made of a material including at least one of Ag, Cu, AgCu, and AgCuTi. If the second bonding layer 20 is the brazing bonding layer, the second bonding layer 20 may be disposed between the lower metal layer 130 of the ceramic substrate 100 and the plane part 310 of the heat sink 300, and may integrally bond the ceramic substrate 100 and the heat sink 300 at a brazing temperature. The brazing temperature may be 450° C. or more. Ag, AgCu, and AgCuTi can each improve heat dissipation efficiency by playing a role of increasing an adhesive force and also facilitating the transfer of heat between the ceramic substrate 100 and the heat sink 300 due to high thermal conductivity. The second bonding layer 20 may be formed by any one method, among plating, paste application, and foil attachment, and may have a thickness of about 0.005 mm to 1.0 mm.

If the second bonding layer 20 is the Ag sintering bonding layer, Ag sintering paste may be disposed between the lower metal layer 130 of the ceramic substrate 100 and the plane part 310 of the heat sink 300. The ceramic substrate 100 and the heat sink 300 may be bonded by sintering the Ag sintering paste at a low temperature of about 200° C. Such Ag sintering bonding has high high-temperature safety and excellent bonding strength of about 80 MPa because the melting point of a sintering body rises to 700° C. or more after the bonding.

Meanwhile, the ceramic substrate 100 and the heat sink 300 may be temporarily bonded through thermochemical bonding and then brazing-bonded. In this case, the thermochemical bonding may be bonding using heat fusion, adhesives, a sticking agent, etc. As described above, the ceramic substrate 100 and the heat sink 300 may be airtightly bonded by a bonding method, such as brazing bonding or Ag sintering bonding, and may each have high bonding strength by which the ceramic substrate and the heat sink can withstand water pressure, oil pressure, etc.

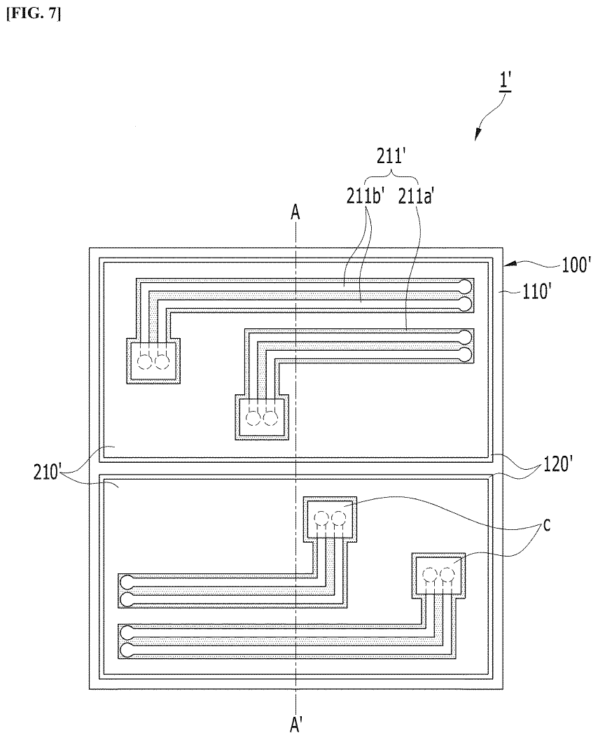

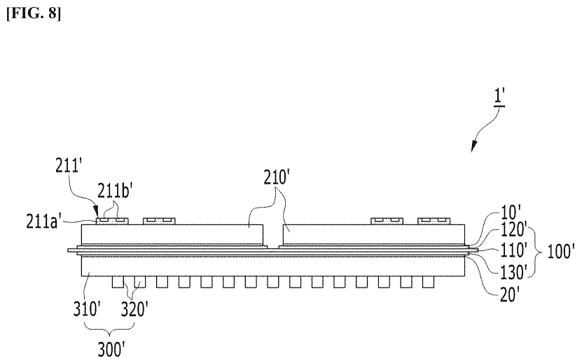

Hereinafter, a ceramic substrate unit according to another embodiment of the present disclosure is described with reference to FIGS. 7 and 8. For convenience of description, a description of the same component as that in the embodiment illustrated in FIGS. 1 to 6 is omitted, and a difference is mainly described hereinafter.

FIG. 7 is a plane view illustrating the ceramic substrate unit according to another embodiment of the present disclosure. FIG. 8 is a cross-sectional view taken along line A-A′ in FIG. 7.

As illustrated in FIGS. 7 and 8, in a ceramic substrate unit 1′ according to another embodiment of the present disclosure, a wiring part 211′ may be bonded to an upper surface of a first heat dissipation spacer 210′, and a semiconductor chip c may be directly bonded to one end of an electrode 211b′ of the wiring part 211′ in a flip chip form. As described above, the semiconductor chip c may be directly bonded to the one end of the electrode 211b′ in a flip chip form without the second heat dissipation spacer 220. Accordingly, an inductance value can be lowered to the maximum because wire bonding is omitted. An electrical risk factor which may occur upon wire bonding can be removed, a rate voltage or current can be converted, and reliability and efficiency upon use for high power can be improved.

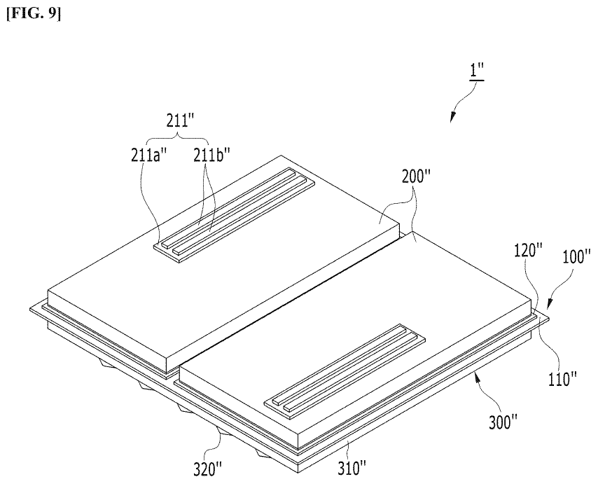

Hereinafter, a ceramic substrate unit according to still another embodiment of the present disclosure is described with reference to FIGS. 9 to 12. For convenience of description, a description of the same component as that in the embodiment illustrated in FIGS. 1 to 6 is omitted, and a difference is mainly described hereinafter.

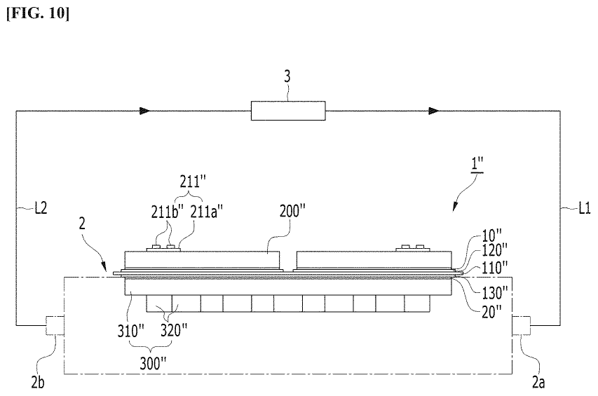

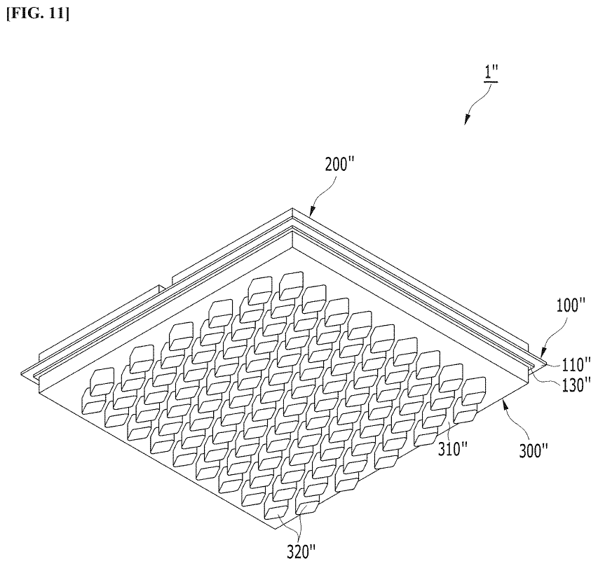

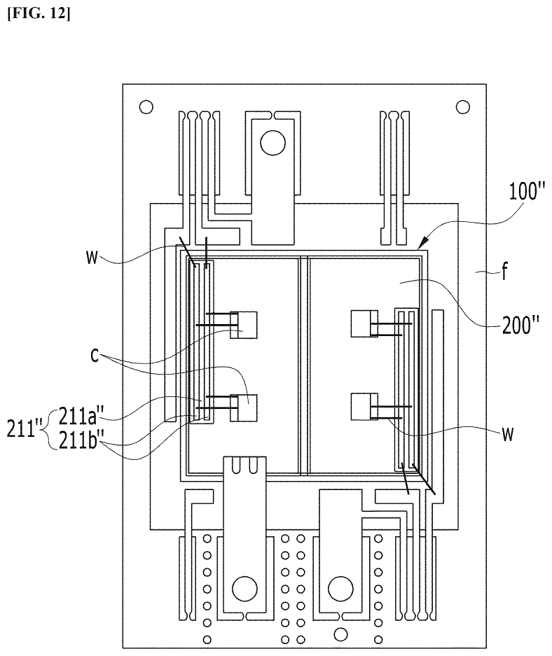

FIG. 9 is a plane-side perspective view illustrating a ceramic substrate unit according to still another embodiment of the present disclosure. FIG. 10 is a conceptual view illustrating a construction in which the ceramic substrate unit according to still another embodiment of the present disclosure is mounted on a refrigerant circulation part and a circulation driving part is connected to the refrigerant circulation part. FIG. 11 is a bottom-side perspective view illustrating the ceramic substrate unit according to still another embodiment of the present disclosure. FIG. 12 is a plane view illustrating a construction in which a semiconductor chip and a lead frame are connected to the ceramic substrate unit according to still another embodiment of the present disclosure.

As illustrated in FIGS. 9 and 10, a ceramic substrate unit 1″ according to still another embodiment of the present disclosure may be constructed to include a ceramic substrate 100″ in which metal layers 120″ and 130″ are provided on upper and lower surfaces of the ceramic base 110″, a heat dissipation spacer 200″ that is bonded to the upper metal layer 120″ of the ceramic substrate 100″ and on which the semiconductor chip c is mounted, a wiring part 211″ including an insulating layer 211a″ that is bonded to an upper surface of the heat dissipation spacer 200″ and an electrode 211b″ that is disposed on the insulating layer 211a″ and connected to the semiconductor chip c to form a wire, and a heat sink 300″ that is bonded to the lower metal layer 130″ of the ceramic substrate 100″.

In the ceramic substrate unit 1″ according to still another embodiment of the present disclosure, the insulating layer 211a″ of the wiring part 211″ may have a bar shape unlike the “L” form in the embodiment, and may be made of an insulating material. For example, polyimide (PI), FR4, and ceramic (alumina, ZTA, AlN, Si₃N₄, etc.) may be used as the insulating layer. Furthermore, the insulating layer 211a″ may be formed in the range of a thickness of approximately 0.015 mm to 0.25 mm.

The electrode 211b″ of the wiring part 211″ may be disposed on the insulating layer 211a″, and may be extended in one direction thereof to form a wire. The electrode 211b″ may be formed on an upper surface of the insulating layer 211a″ in a length direction thereof, and may be provided as a pair. The pair of electrodes may be disposed at an interval in the width direction of the insulating layer 211a″. The electrode 211b′ may be made of metal or an alloy material having electrical conductivity and thermal conductivity so that the electrode plays an electrical signal role or a power movement track role for power conversion. For example, Cu, Ag, Ni—Au, W, Mo, MoW, etc. may be used as the electrode 211b′. For example, the wiring part 211″ may be formed by bonding a PI and Cu sheet by thermoplastic polyimide (TPI) or may be formed by forming a metal layer on a ceramic base and then simultaneously plasticizing the metal layer and the ceramic base. Furthermore, the wiring part 211″ may be designed to have a withstand voltage of 3 kV or more and heat resistance of at least 250° C. or more.

Referring to FIG. 11, in the ceramic substrate unit 1″ according to still another embodiment of the present disclosure, a plurality of protrusions 320″, each one having a diamond-shaped cross section, may be disposed in the heat sink 300″ at intervals.

Referring to FIG. 12, the electrode 211b′ has one side connected to a semiconductor chip c by a wire w and the other side connected to a lead frame f by a wire w, and thus may play a role as an electric track that transfers an electrical signal. As described above, in the still another ceramic substrate unit 1″ of the present disclosure, the wiring part 211″ that plays a role as the electric track may be bonded to an upper surface of the heat dissipation spacer 200″ and connected to the semiconductor chip c that is mounted on the upper surface of the heat dissipation spacer 200″. In general, the heat dissipation spacer 200″ has a thickness of about 2 t, and is much thicker than the upper metal layer 120″ of the ceramic substrate 100″, which has a thickness of 0.3 t. The heat dissipation spacer 200″ has problems in that it is difficult to form an electrode signal line portion or a wire bonding area for the connection of a circuit by etching using equipment and a long etching time is taken because the heat dissipation spacer has a thickness of 1.2 t or more and is made of a conductive material as described above. In the ceramic substrate unit 1″ according to still another embodiment of the present disclosure, the heat dissipation spacer 200″ does not need to be etched for the connection of a circuit and an electrode pattern design can be freely performed, because the wiring part 211″ playing a role as an electric track is aligned and bonded to the upper surface of the heat dissipation spacer 200″ after the wiring part is separately processed in order to solve the problems.

The insulating layer 211a″ of the wiring part 211″ may be bonded to the upper surface of the heat dissipation spacer 200″ via a brazing bonding layer (not illustrated). In this case, the brazing bonding layer may be made of a material including at least one of Ag, Cu, AgCu, and AgCuTi. The brazing bonding layer may be disposed between a lower surface of the insulating layer 211a″ and the upper surface of the heat dissipation spacer 200″, and may integrally bond the wiring part 211″ and the heat dissipation spacer 200″ at a brazing temperature. The brazing temperature may be 450° C. or more.

Hereinafter, a method of manufacturing a ceramic substrate unit according to an embodiment of the present disclosure is described with reference to FIGS. 1 to 6 and 13.

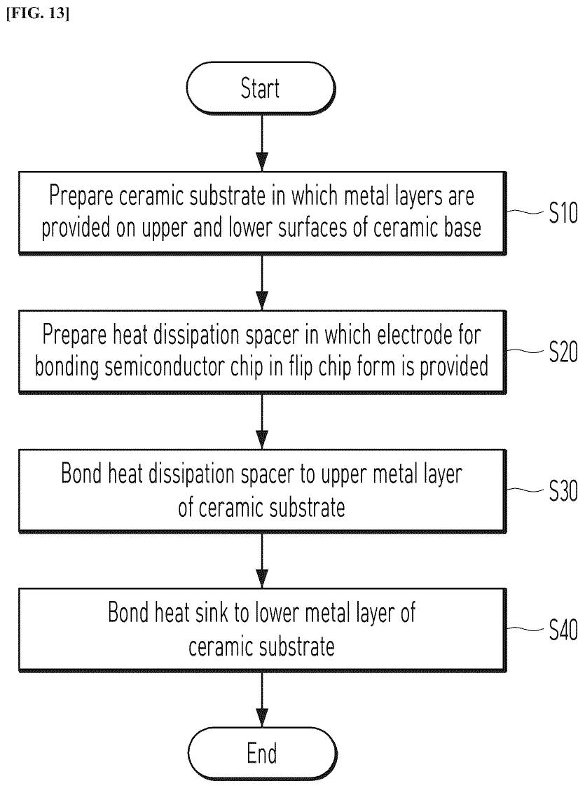

FIG. 13 is a flowchart illustrating a method of manufacturing a ceramic substrate unit according to an embodiment of the present disclosure.

Referring to FIGS. 1 to 6 and 13, the method of manufacturing a ceramic substrate according to an embodiment of the present disclosure may include a step S10 of preparing the ceramic substrate 100 in which the metal layers 120 and 130 are provided on the upper and lower surfaces of the ceramic base 110, a step S20 of preparing the heat dissipation spacer 200 including the electrode 211b for bonding the semiconductor chip c in a flip chip form, a step S30 of bonding the heat dissipation spacer 200 to the upper metal layer 120 of the ceramic substrate 100, and a step S40 of bonding the heat sink 300 to the lower metal layer 130 of the ceramic substrate 100. In this case, the steps may be sequentially performed or may be performed in a different order, and may be performed substantially simultaneously.

In the step S10 of preparing the ceramic substrate 100, the ceramic substrate 100 may be any one of an active metal brazing (AMB) substrate, a direct bonded copper (DBC) substrate, and a thick printing copper (TPC) substrate. In this case, the ceramic substrate 100 may include the ceramic base 110, and the upper metal layer 120 and the lower metal layer 130 on the upper and lower surfaces of the ceramic base 110 in order to increase heat dissipation efficiency of heat that is generated from the semiconductor chip.

In the step S20 of preparing the heat dissipation spacer 200, the heat dissipation spacer 200 has a shape corresponding to the upper metal layer 120 of the ceramic substrate 100. The heat dissipation spacer 200 may include the first heat dissipation spacer 210 having a lower surface bonded to the upper metal layer 120 and including the wiring part 211 including the electrode 211b and the at least one second heat dissipation spacer 220 that is disposed at a location that faces one end of the electrode 211b and that has an upper surface bonded to the electrode of the semiconductor chip c.

In this case, the wiring part 211 of the first heat dissipation spacer 210 may be constructed to include the insulating layer 211a and the electrode 211b. Specifically, the insulating layer 211a may be disposed in the groove h that is formed at the top of the first heat dissipation spacer 210, and may be made of an insulating material. For example, polyimide (PI), FR4, and ceramic (alumina, ZTA, AlN, Si₃N₄, etc.) may be used as the insulating layer, but the present disclosure is not limited thereto. The electrode 211b may be disposed on the insulating layer 211a. In this case, the electrode 211b may be disposed to be inserted at a predetermined depth on an upper surface of the insulating layer 211a, and may be provided as a pair. The pair of electrodes may be disposed at an interval in the width direction of the insulating layer 211a.

The electrode 211b may form a wire by extending along the groove h of the first heat dissipation spacer 210 from one end disposed at a location that faces the second heat dissipation spacer 220. That is, the electrode 211b has the one end disposed at the location that faces the second heat dissipation spacer 220, and thus may play a role as an electric track that transfers an electrical signal by being connected to the semiconductor chip c bonded to the second heat dissipation spacer 220. For example, Cu, Ag, Ni—Au, W, Mo, MoW, etc. may be used as the electrode 211b, but the present disclosure is not limited thereto.

In the step S20 of bonding the heat dissipation spacer 200 to the upper metal layer 120 of the ceramic substrate 100, the heat dissipation spacer 200 is bonded to the upper metal layer 120 via the first bonding layer 10 that is disposed between the upper metal layer 120 of the ceramic substrate 100 and the heat dissipation spacer 200. The first bonding layer 10 may be made of a material including at least one of Ag, Cu, AgCu, and AgCuTi, or may be made of Ag sintering paste. If the first bonding layer 10 is a brazing bonding layer made of the material including at least one of Ag, Cu, AgCu, and AgCuTi, the brazing bonding layer may be disposed between the upper metal layer 120 of the ceramic substrate 100 and the heat dissipation spacer 200, and may integrally bond the ceramic substrate 100 and the heat dissipation spacer 200 at a brazing temperature. The brazing temperature may be 450° C. or more. The first bonding layer 10 may be formed by any one method, among plating, paste application, and foil attachment, and may have a thickness of about 0.005 mm to 1.0 mm.

If the first bonding layer 10 is an Ag sintering bonding layer, the Ag sintering paste may be disposed between the upper metal layer 120 of the ceramic substrate 100 and the heat dissipation spacer 200. The ceramic substrate 100 and the heat dissipation spacer 200 may be bonded by sintering the Ag sintering paste at a low temperature of about 200° C. Such Ag sintering bonding has high high-temperature safety and has excellent bonding strength of about 80 MPa because the melting point of a sintering body rises to 700° C. or more after the bonding.

In the step S40 of bonding the heat sink 300 to the lower metal layer 130 of the ceramic substrate 100, the heat sink 300 may be made of a material having high thermal conductivity, such as Cu, Al, and a Cu alloy, for heat dissipation, and may include the plane part 310 and the plurality of protrusions 320. The plane part 310 has an upper surface that is a portion coming into direct contact with the lower metal layer 130, and may be provided in a flat panel form in order to increase a bonding area to the maximum. The plurality of protrusions 320 may be disposed on a lower surface of the plane part 310 at intervals. The plurality of protrusions 320 may be disposed in the external refrigerant circulation part 2, and may be provided to come into direct contact with a liquid refrigerant that circulates through the refrigerant circulation part 2.

The present embodiment illustrates the slit type heat sink 300 in which the plurality of protrusions 320 each having a rod shape are horizontally disposed at intervals, but the present disclosure is not limited thereto. The plurality of protrusions 320 may be provided in various pin forms, such as a cylinder, a polygonal column, a teardrop shape, and a diamond shape. A shape of the protrusion 320 may be implemented by molding processing, etching processing, milling, or other processing. In the present embodiment, in the step S40 of bonding the heat sink 300 to the lower metal layer 130 of the ceramic substrate 100, an example in which the plurality of protrusions 320 has been provided is described, but the plurality of protrusions 320 may be formed after the step S40 of the bonding. For example, the plurality of protrusions 320 may be formed by preparing the heat sink 300 having a thick flat panel form, bonding the heat sink to the lower metal layer 130 of the ceramic substrate 100, and then removing a part of them by etching process, milling processing, etc.

In the step S40 of bonding the heat sink 300 to the lower metal layer 130 of the ceramic substrate 100, the heat sink 300 is bonded to the lower metal layer 130 via the second bonding layer 20 that is disposed between the lower metal layer 130 of the ceramic substrate 100 and the plane part 310 of the heat sink 300. The second bonding layer 20 may be made of a material including at least one of Ag, Cu, AgCu, and AgCuTi, or may be made of Ag sintering paste. If the second bonding layer 20 is a brazing bonding layer made of the material including at least one of Ag, Cu, AgCu, and AgCuTi, the second bonding layer 20 may be disposed between the lower metal layer 130 of the ceramic substrate 100 and the plane part 310 of the heat sink 300, and may integrally bond the ceramic substrate 100 and the heat sink 300 at a brazing temperature. The brazing temperature may be 450° C. or more. The second bonding layer 20 may be formed by any one method, among plating, paste application, and foil attachment, and may have a thickness of about 0.005 mm to 1.0 mm.

If the second bonding layer 20 is an Ag sintering bonding layer, the Ag sintering paste may be disposed between the lower metal layer 130 of the ceramic substrate 100 and the plane part 310 of the heat sink 300. The ceramic substrate 100 and the heat sink 300 may be bonded by sintering the Ag sintering paste at a low temperature of about 200° C. Such Ag sintering bonding has high high-temperature safety and excellent bonding strength of about 80 MPa because the melting point of a sintering body rises to 700° C. or more after the bonding.

The ceramic substrate unit according to embodiments of the present disclosure can further improve performance of a power module because the ceramic substrate unit can secure both multi-access and multi-quantity access and heat dissipation effect of a semiconductor chip and also contributes to miniaturization by being applied to the power module.

The ceramic substrate unit according to embodiments of the present disclosure may also be applied to various module parts that are used in high power in addition to the power module.

The above description is merely a description of the technical spirit of the present disclosure, and those skilled in the art may change and modify the present disclosure in various ways without departing from the essential characteristic of the present disclosure. Accordingly, the embodiments described in the present disclosure should not be construed as limiting the technical spirit of the present disclosure, but should be construed as describing the technical spirit of the present disclosure. The technical spirit of the present disclosure is not restricted by the embodiments. The range of protection of the present disclosure should be construed based on the following claims, and all of technical spirits within an equivalent range of the present disclosure should be construed as being included in the scope of rights of the present disclosure.

1. A ceramic substrate unit comprising:
a ceramic substrate in which metal layers are provided on upper and lower surfaces of a ceramic base;
a heat dissipation spacer bonded to the upper metal layer of the ceramic substrate; and
a heat sink bonded to the lower metal layer of the ceramic substrate,
wherein the heat dissipation spacer comprises an electrode in an area to which a semiconductor chip is bonded so that the semiconductor chip is bonded to the heat dissipation spacer in a flip chip form.

2. The ceramic substrate unit of claim 1, wherein the at least two semiconductor chips are bonded to the heat dissipation spacer.

3. The ceramic substrate unit of claim 1, wherein the heat dissipation spacer comprises:
a first heat dissipation spacer that has a shape corresponding to the upper metal layer and has a lower surface bonded to the upper metal layer and that comprises a wiring part comprising the electrode; and
at least one second heat dissipation spacer that is disposed at a location that faces one end of the electrode and that has an upper surface bonded to the electrode of the semiconductor chip.

4. The ceramic substrate unit of claim 3, wherein the wiring part comprises:
an insulating layer disposed in a groove formed on the first heat dissipation spacer and made of an insulating material; and
the electrode disposed on the insulating layer and extended along the groove from the one end to form a wire.

5. The ceramic substrate unit of claim 4, wherein:
the electrode is disposed to be inserted at a predetermined depth on an upper surface of the insulating layer and provided as a pair, and
the pair of electrodes is disposed at an interval in a width direction of the insulating layer.

6. The ceramic substrate unit of claim 1, wherein the heat sink comprises:
a plane part having an upper surface coming into contact with the lower metal layer; and
a plurality of protrusions disposed on a lower surface of the plane part at intervals and configured to form a passage along which a liquid refrigerant flows.

7. The ceramic substrate unit of claim 6, wherein:
the plurality of protrusions is disposed in an external refrigerant circulation part, and
the liquid refrigerant that circulates through the refrigerant circulation part is heat-exchanged with the plurality of protrusions.

8. The ceramic substrate unit of claim 6, wherein the plurality of protrusions each has a rod shape and is horizontally disposed at intervals.

9. The ceramic substrate unit of claim 6, wherein the plurality of protrusions each has at least one pin shape, among a cylinder, a polygonal column, a teardrop shape, or a diamond shape.

10. The ceramic substrate unit of claim 1, wherein a material of the heat sink is any one of Cu, Al, and a Cu alloy.

11. The ceramic substrate unit of claim 1, wherein the heat dissipation spacer is made of a CPC material in which Cu or MoCu or Cu, CuMo, and Cu have been sequentially stacked.

12. A ceramic substrate unit comprising:
a ceramic substrate in which metal layers are provided on upper and lower surfaces of a ceramic base;
a heat dissipation spacer that is bonded to the upper metal layer of the ceramic substrate and on which a semiconductor chip is mounted;
a wiring part comprising an insulating layer bonded to an upper surface of the heat dissipation spacer and an electrode disposed on the insulating layer and connected to the semiconductor chip to form a wire; and
a heat sink bonded to the lower metal layer of the ceramic substrate.

13. The ceramic substrate unit of claim 12, wherein:
the insulating layer of the wiring part is boned to the upper surface of the heat dissipation spacer via a brazing bonding layer, and
the brazing bonding layer is made of a material comprising at least one of Ag, Cu, AgCu, and AgCuTi.

14. The ceramic substrate unit of claim 12, wherein the electrode of the wiring part is connected to the semiconductor chip through a wire.

15. A method of manufacturing a ceramic substrate unit, comprising:
a step of preparing a ceramic substrate in which metal layers are provided on upper and lower surfaces of a ceramic base;
a step of preparing a heat dissipation spacer comprising an electrode for bonding a semiconductor chip in a flip chip form;
a step of bonding the heat dissipation spacer to the upper metal layer of the ceramic substrate; and
a step of bonding a heat sink to the lower metal layer of the ceramic substrate.

16. The ceramic substrate unit of claim 15, wherein in the step of preparing the heat dissipation spacer, the heat dissipation spacer comprises:
a first heat dissipation spacer that has a shape corresponding to the upper metal layer and has a lower surface bonded to the upper metal layer and that comprises a wiring part comprising the electrode; and
at least one second heat dissipation spacer that is disposed at a location that faces one end of the electrode and that has an upper surface bonded to the electrode of the semiconductor chip.

17. The ceramic substrate unit of claim 16, wherein in the step of preparing the heat dissipation spacer, the wiring part comprises:
an insulating layer disposed in a groove formed on the first heat dissipation spacer and made of an insulating material; and
the electrode disposed on the insulating layer and extended along the groove from the one end to form a wire.

18. The ceramic substrate unit of claim 17, wherein in the step of preparing the heat dissipation spacer,
the electrode is disposed to be inserted at a predetermined depth on an upper surface of the insulating layer and provided as a pair, and
the pair of electrodes is disposed at an interval in a width direction of the insulating layer.

19. The ceramic substrate unit of claim 15, wherein in the step of bonding the heat dissipation spacer to the upper metal layer of the ceramic substrate,
the heat dissipation spacer is bonded to the upper metal layer via a first bonding layer that is disposed between the upper metal layer and the heat dissipation spacer, and
the first bonding layer is made of a material comprising at least one of Ag, Cu, AgCu, and AgCuTi or made of Ag sintering paste.

20. The ceramic substrate unit of claim 15, wherein in the step of bonding the heat sink to the lower metal layer of the ceramic substrate,
the heat sink is bonded to the lower metal layer via a second bonding layer that is disposed between the lower metal layer and a plane part of the heat sink, and
the second bonding layer is made of a material comprising at least one of Ag, Cu, AgCu, and AgCuTi or made of Ag sintering paste.
